(19) United States
(12) Patent Application Publication
(10) Pub. No.: US 2026/0101674 A1
(43) Pub. Date: Apr. 9, 2026

(54) MAGNETIC MEMORY DEVICE AND METHOD FOR MANUFACTURING THE SAME

(71) Applicant: Samsung Electronics Co., Ltd., Suwon-si (KR)

(72) Inventors: Bae-Seong Kwon, Suwon-si (KR); Min Kwon Cho, Suwon-si (KR); Shin Hee Han, Suwon-si (KR)

(21) Appl. No.: 19/202,393

(22) Filed: May 8, 2025

(30) Foreign Application Priority Data
Oct. 4, 2024 (KR) 10-2024-0135023

(51) Int. Cl. H10N 50/10; G11C 11/16; H10B 61/00; H10N 50/80

(52) U.S. Cl. CPC H10N 50/10; H10B 61/22; H10N 50/80; G11C 11/161

(57) ABSTRACT

A magnetic memory device includes a substrate including cell, peripheral, and interface regions, a lower insulating film, lower electrode contacts extending into the lower insulating film, information storage patterns on the lower insulating film, a cell insulating film that is between adjacent ones of the information storage patterns and is on the lower insulating film, an upper insulating film free from overlap with the peripheral region, and a peripheral insulating film on the peripheral region of the substrate. The information storage patterns include magnetic tunnel junction patterns, first information storage patterns on the cell region of the substrate, and second information storage patterns on the interface region of the substrate, the first information storage patterns are electrically connected to respective ones of the lower electrode contacts, and the second information storage patterns are electrically insulated from the lower electrode contacts.

### CROSS-REFERENCE TO RELATED APPLICATION

This application claims priority from Korean Patent Application No. 10-2024-0135023 filed on Oct. 4, 2024, in the Korean Intellectual Property Office, and all the benefits accruing therefrom under 35 U.S.C. 119, the contents of which in its entirety are herein incorporated by reference.

### TECHNICAL FIELD

The present disclosure relates to a magnetic memory device and a method of manufacturing the same.

### BACKGROUND

Non-volatile memory devices using resistive materials include phase-change random-access memory (PRAM) devices, resistive random-access memory (RRAM) devices, and magnetic random-access memory (MRAM) devices. While dynamic random-access memory (DRAM) devices and flash memory devices store data using electric charge, non-volatile memory devices using resistive materials store data by utilizing state changes of phase-change materials such as chalcogenide alloys (for PRAM devices), resistance changes of variable resistive materials (for RRAM devices), or resistance changes of magnetic tunnel junction (MTJ) thin films according to the magnetization state of ferromagnetic materials (for MRAM devices).

Specifically, MRAM devices have been receiving significant attention due to their fast read and write speeds, high durability, non-volatility, and low power consumption during operation. Furthermore, MRAM devices can store information by using magnetic materials as information storage media.

### SUMMARY

Aspects of the present disclosure provide a magnetic memory device with improved product reliability.

Aspects of the present disclosure also provide a method for a manufacturing a magnetic memory device with improved product reliability.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to an example embodiment of the present disclosure, a magnetic memory device includes a substrate including a cell region, a peripheral region extending around the cell region, and an interface region between the cell region and the peripheral region, a lower insulating film on the cell region and the peripheral region of the substrate, lower electrode contacts extending into the lower insulating film, information storage patterns that are spaced apart from each other in a first direction and are on the lower insulating film, a cell insulating film that is between adjacent ones of the information storage patterns and is on the lower insulating film, an upper insulating film that is on an upper surface of the cell insulating film and are on upper surfaces of the information storage patterns and is free from overlap with the peripheral region of the substrate in a second direction that is perpendicular to the first direction, and a peripheral insulating film on the peripheral region of the substrate. The information storage patterns include magnetic tunnel junction patterns, first information storage patterns on the cell region of the substrate, and second information storage patterns on the interface region of the substrate, the first information storage patterns are electrically connected to respective ones of the lower electrode contacts, and the second information storage patterns are electrically insulated from the lower electrode contacts.

According to an example embodiment of the present disclosure, a method for manufacturing a magnetic memory device includes providing a substrate including a cell region, a peripheral region, and an interface region between the cell region and the peripheral region, forming preliminary information storage patterns on the cell region, the peripheral region, and the interface region of the substrate, where the preliminary information storage patterns are spaced apart from each other in first and second directions and each respectively include first and second magnetic tunnel junction patterns, and forming information storage patterns on the cell region and the interface region of the substrate by removing a portion of the preliminary information storage patterns on the interface region of the substrate.

According to an example embodiment of the present disclosure, a magnetic memory device includes a substrate, an array including information storage patterns that are spaced apart from each other in a first direction and a second direction on the substrate, the information storage patterns including magnetic tunnel junction patterns, and a spacer that extends around at least a portion of the array and is on the substrate. The information storage patterns include normal information storage patterns at a central portion of the array and dummy information storage patterns at a peripheral portion of the array, and where the dummy information storage patterns are electrically insulated from conductive elements in the substrate.

It should be noted that the effects of the present disclosure are not limited to those described above, and other effects of the present disclosure will be apparent from the following description.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is a circuit diagram illustrating a unit memory cell of a magnetic memory device according to some embodiments;

FIG. 2 is a diagram illustrating the magnetic memory device according to some embodiments;

FIG. 3 is an enlarged view of area S in FIG. 2;

FIG. 4 is a cross-sectional view taken along line A-A′ in FIG. 2;

FIG. 5 is a diagram illustrating a magnetic memory device according to some embodiments;

FIG. 6 is a cross-sectional view taken along line A-A′ of FIG. 5;

FIG. 7 is a diagram illustrating a magnetic memory device according to some embodiments;

FIG. 8 is a cross-sectional view taken along line A-A′ of FIG. 7;

FIG. 9 is a diagram illustrating a magnetic memory device according to some embodiments;

FIG. 10 is a cross-sectional view taken along line A-A′ of FIG. 9;

FIG. 11 is a diagram illustrating a magnetic memory device according to some embodiments;

FIG. 12 is a cross-sectional view taken along line B-B′ of FIG. 11;

FIGS. 13 through 21 are diagrams illustrating a method for manufacturing a magnetic memory device according to some embodiments; and

FIG. 22 is a diagram illustrating a method for manufacturing a magnetic memory device according to some embodiments.

### DETAILED DESCRIPTION

To clarify the present disclosure, the same elements or equivalents are referred to by the same reference numerals throughout the specification. Further, since sizes and thicknesses of constituent members shown in the accompanying drawings are arbitrarily given for better understanding and ease of description, the present disclosure is not limited to the illustrated sizes and thicknesses. In the drawings, the thickness of layers, films, panels, regions, etc., are exaggerated for clarity. In the drawings, for better understanding and ease of description, thicknesses of some layers and areas are excessively displayed.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, spatially relative terms, such as “beneath,” “below,” “lower,” “above,” “upper,” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations), and the spatially relative descriptors used herein may be interpreted accordingly.

In addition, unless explicitly described to the contrary, the word “comprises”, and variations such as “comprises” or “comprising”, will be understood to imply the inclusion of stated elements but not the exclusion of any other elements. As used herein, the singular forms “a,” “an” and “the” are intended to include the plural forms as well, unless the context clearly indicates otherwise. The term “and/or” includes any and all combinations of one or more of the associated listed items. The term “connected” may be used herein to refer to a physical and/or electrical connection and may refer to a direct or indirect physical and/or electrical connection. The term “exposed” may be used to define a relationship between particular layers or surfaces, but it does not require the layer or surface to be free of other elements or layers thereon in the completed device. Components or layers described with reference to “overlap” in a particular direction may be at least partially obstructed by one another when viewed along a line extending in the particular direction or in a plane perpendicular to the particular direction. The terms “first,” “second,” etc. may be used herein to merely distinguish one component, element, etc., from another.

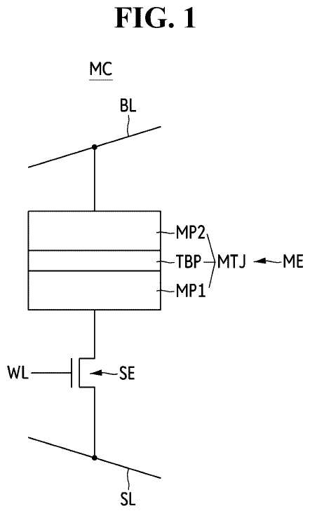

FIG. 1 is a circuit diagram illustrating a unit memory cell of a magnetic memory device according to some embodiments.

Referring to FIG. 1, a unit memory cell MC of the magnetic memory device according to some embodiments may include a memory element ME and a selection element SE.

The memory element ME and the selection element SE may be electrically connected to each other in series. The memory element ME may be connected between a bitline BL and the selection element SE. The selection element SE may be connected between the memory element ME and a source line SL and may be controlled by a wordline WL. The selection element SE may include, for example, a bipolar transistor or a metal-oxide semiconductor field-effect transistor (MOSFET).

The memory element ME may include a magnetic tunnel junction pattern MTJ with first and second magnetic patterns MP1 and MP2, which are spaced apart from each other, and a tunnel barrier pattern TBP between the first and second magnetic patterns MP1 and MP2.

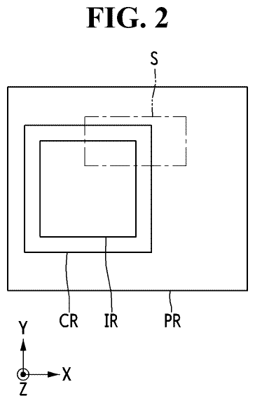

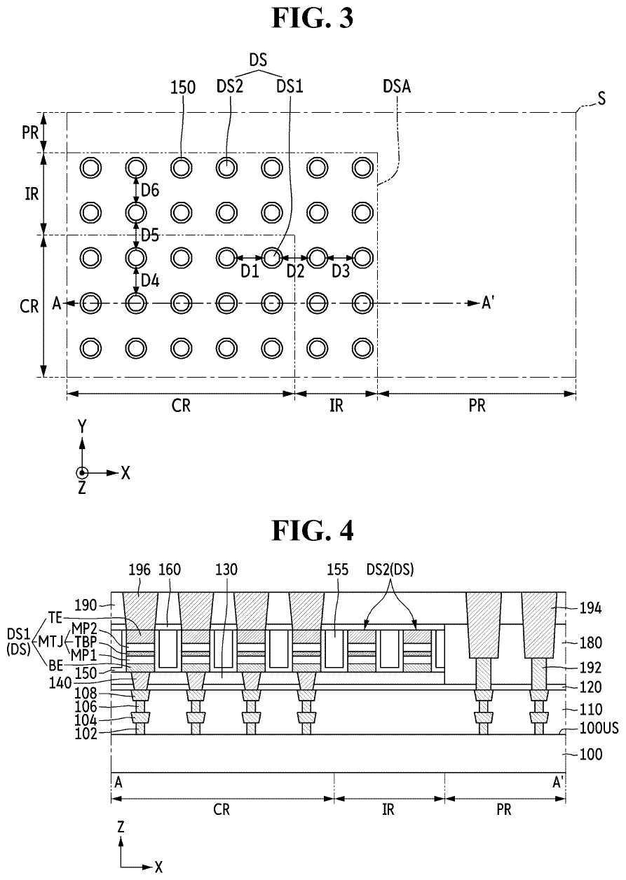

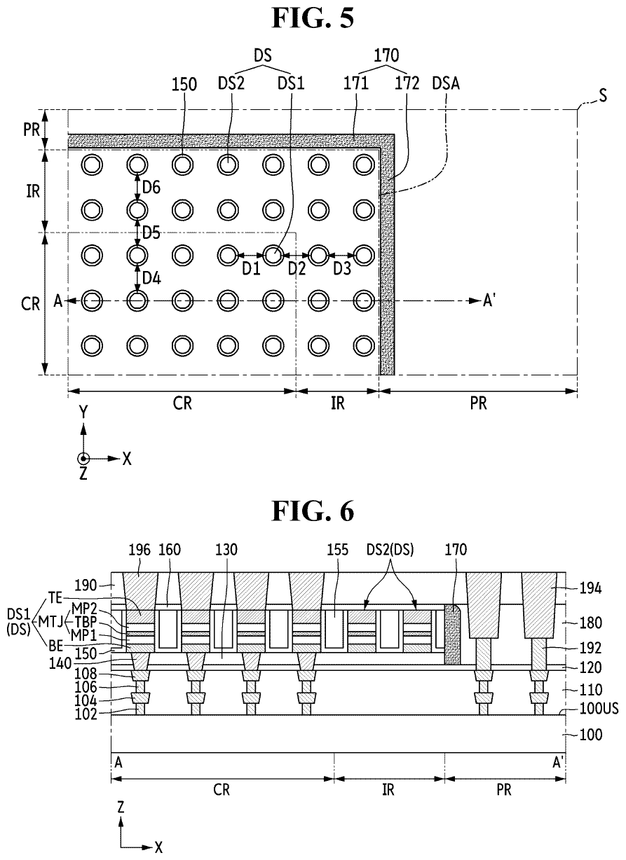

One of the first and second magnetic patterns MP1 and MP2 may be a reference magnetic pattern, which has a single fixed magnetization direction regardless of an external magnetic field under normal operating conditions, and the other magnetic pattern may be a free magnetic pattern whose magnetization direction may be changed between two stable magnetization directions by an external magnetic field. The electrical resistance of the magnetic tunnel junction pattern may be much greater when the magnetization directions of the reference magnetic pattern and the free magnetic pattern are antiparallel compared to when they are parallel. In other words, the electrical resistance of the magnetic tunnel junction pattern may be adjusted by changing the magnetization direction of the free magnetic pattern. Accordingly, the memory element ME can store data in the unit memory cell MC by utilizing the difference in electrical resistance based on the magnetization directions of the reference magnetic pattern and the free magnetic pattern. For example, when the magnetization directions of the reference magnetic pattern and the free magnetic pattern are parallel, the data may be determined as ‘0,’ and when the magnetization directions of the reference magnetic pattern and the free magnetic pattern are antiparallel, the data may be determined as ‘1.’ FIG. 2 is a diagram illustrating the magnetic memory device according to some embodiments. FIG. 3 is an enlarged view of area S in FIG. 2. FIG. 4 is a cross-sectional view taken along line A-A′ in FIG. 2.

Referring to FIGS. 2 through 4, the magnetic memory device according to some embodiments may include a substrate 100, a wiring structure (102, 104, 106, and 108), a wiring insulating film 110, a first lower insulating film 120, a second lower insulating film 130, an array DSA, lower electrode contacts 140, a capping insulating film 150, a cell insulating film 155, an upper insulating film 160, a peripheral insulating film 180, an interlayer insulating film 190, and cell conductive lines 196.

The substrate 100 includes a cell region CR, a peripheral region PR surrounding or extending around the cell region CR, and an interface region IR between the cell region CR and the peripheral region PR. The interface region IR may be interposed between the cell region CR and the peripheral region PR.

Memory cells (“MC” of FIG. 1) may be provided in the cell region CR, and peripheral circuits for driving the memory cells MC may be provided in the peripheral region PR. Peripheral transistors of the peripheral circuits may be disposed on the peripheral region PR of the substrate 100. The peripheral circuits may include a row decoder, a column selection circuit, a read/write circuit, and/or control logic.

Selection elements (“SE” of FIG. 1) may be disposed on the cell region CR of the substrate 100. The selection elements SE and the peripheral transistors may include, for example, field-effect transistors (FETs).

The substrate 100 may be a silicon (Si) or Si-on-insulator (SOI) substrate. In some embodiments, the substrate 100 may include silicon-germanium (SiGe), SiGe-on-insulator (SGOI), indium antimonide, a lead telluride compound, indium arsenide, indium phosphide, gallium arsenide, or gallium antimonide, but is not limited thereto.

The wiring structure (102, 104, 106, and 108) may be disposed on an upper surface 100U of the substrate 100. The wiring structure (102, 104, 106, and 108) may be disposed on both the cell region CR and the peripheral region PR of the substrate 100. Here, a first direction X and a second direction Y intersect each other and are parallel to the upper surface 100U of the substrate 100, and a third direction Z intersects the first direction X and the second direction Y and is perpendicular to the upper surface 100U of the substrate 100.

The wiring structure (102, 104, 106, and 108) may include wiring lines (104 and 108) and wiring contacts (102 and 106). Wiring contacts 102 may be disposed on the substrate 100. Wiring lines 104 may be disposed on the wiring contacts 102. The wiring lines 104 may be electrically connected to the substrate 100 through the wiring contacts 102. The wiring lines 104 may be electrically connected through the wiring contacts 102 to terminals (e.g., source terminals, drain terminals, or gate terminals) of the selection elements SE or of the peripheral transistors. Wiring contacts 106 may be disposed on the wiring lines 104. Wiring lines 108 may be disposed on the wiring contacts 106. The wiring lines 108 may be electrically connected to the wiring lines 104 through the wiring contacts 106. The wiring lines (104 and 108) and the wiring contacts (102 and 106) may each include a metal (e.g., copper (Cu)).

The wiring insulating film 110 may be disposed on the upper surface 100US of the substrate 100. The wiring insulating film 110 may be disposed on the cell region CR, the interface region IR, and the peripheral region PR of the substrate 100. The wiring insulating film 110 may cover or at least partially overlap the wiring structure (102, 104, 106, and 108). The wiring insulating film 110 may at least partially expose the upper surface of the uppermost wiring lines 108. For example, the upper surface of the wiring insulating film 110 may be substantially coplanar with the upper surfaces of the uppermost wiring lines 108. The wiring insulating film 110 may include, for example, silicon oxide, silicon nitride, and/or silicon oxynitride.

The first lower insulating film 120 may be disposed on the wiring insulating film 110. The first lower insulating film 120 may be disposed on the wiring insulating film 110 in the cell region CR, the interface region IR, and the peripheral region PR of the substrate 100. The first lower insulating film 120 may cover or at least partially overlap the exposed upper surfaces of the uppermost wiring lines 108.

The first lower insulating film 120 may include, for example, silicon oxide, silicon nitride, and/or silicon oxynitride. The first lower insulating film 120 may have an etch selectivity relative to the wiring insulating film 110 and/or the second lower insulating film 130. For example, the first lower insulating film 120 may include silicon nitride, and the wiring insulating film 110 and/or the second lower insulating film 130 may include silicon oxide.

The second lower insulating film 130 may be disposed on the first lower insulating film 120 in the cell region CR and the interface region IR. In the cell region CR, the first lower insulating film 120 may be interposed between the wiring insulating film 110 and the second lower insulating film 130. In some embodiments, the second lower insulating film 130 may extend from the cell region CR to the first lower insulating film 120 in the peripheral region PR.

The second lower insulating film 130 may include, for example, silicon oxide, silicon nitride, and/or silicon oxynitride.

The array DSA is disposed on the upper surface 100US of the substrate 100. The array DSA includes information storage patterns DS spaced apart in the first and second directions X and Y. The information storage patterns DS may be arranged in the first and second directions X and Y. The information storage patterns DS may be disposed on the second lower insulating film 130.

The information storage patterns DS may include first information storage patterns DS1 disposed in the central portion of the array DSA and second information storage patterns DS2 disposed in the peripheral portion of the array DSA.

The array DSA may be disposed on the cell region CR and the interface region IR. The first information storage patterns DS1 may be disposed on the cell region CR of the substrate 100. The second information storage patterns DS2 may be disposed on the interface region IR of the substrate 100. The first information storage patterns DS1 may be referred to as normal information storage patterns, and the second information storage patterns DS2 may be referred to as dummy information storage patterns.

The first information storage patterns DS1 may be spaced apart by a first distance D1 in the first direction X. Pairs of adjacent first and second information storage patterns DS1 and DS2 in the first direction X may be spaced apart by a second distance D2. The first distance D1 and the second distance D2 may be substantially the same. Here, the term “distance” may refer to a minimum distance.

The first information storage patterns DS1 may be spaced apart by a second distance D2 in the second direction Y. Pairs of adjacent first and second information storage patterns DS1 and DS2 in the second direction Y may be spaced apart by a fifth distance D5. The fourth distance D4 and the fifth distance D5 may be substantially the same.

In some embodiments, the second information storage patterns DS2 may be disposed in part of the interface region IR adjacent to the cell region CR in the first direction X and part of the interface region IR adjacent to the cell region CR in the second direction Y. In the part of the interface region IR adjacent to the cell region CR in the first direction X, the second information storage patterns DS2 may be disposed along at least one column extending in the second direction Y. In the part of the interface region IR adjacent to the cell region CR in the second direction Y, the second information storage patterns DS2 may be disposed along at least one row extending in the first direction X.

For example, in the part of the interface region IR adjacent to the cell region CR in the first direction X, the second information storage patterns DS2 may be disposed along multiple columns to be spaced apart from each other, and in the part of the interface region IR adjacent to the cell region CR in the second direction Y, the second information storage patterns DS2 may be disposed along multiple rows to be spaced apart from each other. The numbers of such rows and columns may be the same or different. The second information storage patterns DS2 may be spaced apart by a third distance D3 in the first direction X. The third distance D3 may be substantially the same as the first and second distances D1 and D2. The second information storage patterns DS2 may be spaced apart by a sixth distance D6. The sixth distance D6 may be substantially the same as the fourth and fifth distances D4 and D5.

As another example, in the part of the interface region IR adjacent to the cell region CR in the first direction X, the second information storage patterns DS2 may be disposed along one column to be spaced apart from each other, and in the part of the interface region IR adjacent to the cell region CR in the second direction Y, the second information storage patterns DS2 may be disposed along multiple rows to be spaced apart from each other.

As yet another example, in the part of the interface region IR adjacent to the cell region CR in the first direction X, the second information storage patterns DS2 may be disposed along multiple columns to be spaced apart from each other, and in the part of the interface region IR adjacent to the cell region CR in the second direction Y, the second information storage patterns DS2 may be disposed along one row to be spaced apart from each other.

In a further example, in the part of the interface region IR adjacent to the cell region CR in the first direction X, the second information storage patterns DS2 may be disposed along one column to be spaced apart from each other, and in the part of the interface region IR adjacent to the cell region CR in the second direction Y, the second information storage patterns DS2 may be disposed along one row to be spaced apart from each other.

In some embodiments, the second information storage patterns DS2 may be disposed only in one of the part of the interface region IR adjacent to the cell region CR in the first direction X or the part of interface region IR adjacent to the cell region CR in the second direction Y.

From a planar perspective, the first information storage patterns DS1 may have a circular shape. In some embodiments, the second information storage patterns DS2 may also have a circular shape from a planar perspective.

The lower electrode contacts 140 may be disposed in the second lower insulating film 130 on the cell region CR. The lower electrode contacts 140 may be disposed between the first information storage patterns DS1 and the substrate 100. The lower electrode contacts 140 may penetrate or extend into the first and second lower insulating films 120 and 130 on the cell region CR and may be electrically connected to the wiring lines 108.

The lower electrode contacts 140 may include at least one of a doped semiconductor material (e.g., doped Si), a metal (e.g., tungsten (W), titanium (Ti), and/or tantalum (Ta)), a metal-semiconductor compound (e.g., a metal silicide), or a conductive metal nitride (e.g., titanium nitride, tantalum nitride, and/or tungsten nitride).

The first information storage patterns DS1 and the second information storage patterns DS2 have the same structure. The first information storage patterns DS1 and the second information storage patterns DS2 may each include a lower electrode BE, a magnetic tunnel junction pattern MTJ, and an upper electrode TE. The magnetic tunnel junction patterns MTJ may be disposed between the lower electrodes BE and the upper electrodes TE.

The lower electrode contacts 140 may be electrically connected to the first information storage patterns DS1. The lower electrode contacts 140 may be connected to the lower electrodes BE of the first information storage patterns DS1.

The lower electrodes BE may include, for example, a conductive metal nitride (e.g., titanium nitride or tantalum nitride). The upper electrodes TE may include at least one of a metal (e.g., Ta, W, Ru, Ir, etc.) or a conductive metal nitride (e.g., TiN).

The magnetic tunnel junction patterns MTJ may include first magnetic patterns MP1, second magnetic patterns MP2, and tunnel barrier patterns TBP between the first magnetic patterns MP1 and the second magnetic patterns MP2. The first magnetic patterns MP1 may be disposed between the lower electrodes BE and the tunnel barrier patterns TBP, and the second magnetic patterns MP2 may be disposed between the upper electrodes TE and the tunnel barrier patterns TBP.

The first magnetic patterns MP1 may be reference layers having a single fixed magnetization direction, and the second magnetic patterns MP2 may be free layers whose magnetization direction may be changed to be parallel or antiparallel to the magnetization direction of the first magnetic patterns MP1.

For example, the magnetization direction of the first magnetic patterns MP1 and the magnetization direction of the second magnetic patterns MP2 may be perpendicular to the interfaces between the tunnel barrier patterns TBP and the second magnetic patterns MP2. In this case, the first magnetic patterns MP1 and the second magnetic patterns MP2 may each include at least one of an intrinsic perpendicular magnetic material and an extrinsic perpendicular magnetic material. The intrinsic perpendicular magnetic material may include a material with perpendicular magnetization characteristics even without external influences. The intrinsic perpendicular magnetic material may include at least one of a perpendicular magnetic material (e.g., CoFeTb, CoFeGd, or CoFeDy), a perpendicular magnetic material with an L10 structure, CoPt with a hexagonal close-packed lattice structure, or a perpendicular magnetic structure. The perpendicular magnetic material with an L10 structure may include at least one of FePt with an L10 structure, FePd with an L10 structure, CoPd with an L10 structure, or CoPt with an L10 structure. The perpendicular magnetic structure may include an alternating and repeated stack of magnetic layers and non-magnetic layers. For example, the perpendicular magnetic structure may include at least one of (Co/Pt)ₙ, (CoFe/Pt)ₙ, (CoFe/Pd)ₙ, (Co/Pd)ₙ, (Co/Ni)ₙ, (CoNi/Pt)ₙ, (CoCr/Pt)ₙ, or (CoCr/Pd)ₙ, where n is the number of layers. The extrinsic perpendicular magnetic material may include a material intrinsic horizontal magnetization characteristics but that exhibits perpendicular magnetization characteristics due to external factors. For example, the extrinsic perpendicular magnetic material may exhibit perpendicular magnetization characteristics due to magnetic anisotropy induced by the junctions between the first magnetic patterns MP1 (or the second magnetic patterns MP2) and the tunnel barrier patterns TBP. The extrinsic perpendicular magnetic material may include, for example, CoFeB.

As another example, the magnetization direction of the first magnetic patterns MP1 and the magnetization direction of the second magnetic patterns MP2 may be parallel to the interfaces between the tunnel barrier patterns TBP and the second magnetic patterns MP2. In this case, the first magnetic patterns MP1 and the second magnetic patterns MP2 may each include a ferromagnetic material. The first magnetic patterns MP1 may further include an antiferromagnetic material to fix the magnetization direction of the ferromagnetic material within the first magnetic patterns MP1.

The tunnel barrier patterns TBP may include, for example, at least one of a magnesium oxide film, a titanium oxide film, an aluminum oxide film, a magnesium-zinc oxide film, or a magnesium-boron oxide film.

The capping insulating film 150 may be disposed on the second lower insulating film 130 over the cell region CR and the interface region IR. The capping insulating film 150 may extend along the side surfaces of the information storage patterns DS and the upper surface of the second lower insulating film 130 over the cell region CR and the interface region IR. The capping insulating film 150 may extend along the side surfaces of the lower electrodes BE, the magnetic tunnel junction patterns MTJ, and the upper electrodes TE. The capping insulating film 150 may at least partially expose the upper surfaces of the information storage patterns DS. From a planar perspective, the capping insulating film 150 may surround or extend around the side surfaces of the information storage patterns DS. From a planar perspective, the capping insulating film 150 may surround or extend around the side surfaces of the lower electrodes BE, the magnetic tunnel junction patterns MTJ, and the upper electrodes TE.

The capping insulating film 150 may include a nitride (for example, silicon nitride).

The cell insulating film 155 may be disposed on the second lower insulating film 130 over the cell region CR and the interface region IR and may fill or be in the spaces between the information storage patterns DS. The capping insulating film 150 may be interposed between the side surfaces of the information storage patterns DS and the cell insulating film 155 and may extend between the cell insulating film 155 and the upper surface of the second lower insulating film 130 over the cell region CR and the interface region IR.

The cell insulating film 155 may include, for example, silicon oxide, silicon nitride, and/or silicon oxynitride. For example, the cell insulating film 155 may include tetra-ethyl ortho-silicate (TEOS) oxide.

The upper insulating film 160 may be disposed on the cell insulating film 155 over the cell region CR and the interface region IR. The upper insulating film 160 may cover the information storage patterns DS and the cell insulating film 155. The upper insulating film 160 may not be disposed over (e.g., is free from overlap in the Z direction) the peripheral region PR of the substrate 100.

The upper insulating film 160 may have an etch selectivity with respect to the cell insulating film 155 and may include a material different from that of the cell insulating film 155. For example, the upper insulating film 160 may include silicon nitride (e.g., SiCN), and the cell insulating film 155 may include silicon oxide.

The peripheral insulating film 180 may be disposed on the first lower insulating film 120 over the peripheral region PR. The peripheral insulating film 180 may contact the side surfaces of the upper insulating film 160, the side surfaces of the capping insulating film 150, the side surfaces of the cell insulating film 155, and the side surfaces of the second lower insulating film 130. The side surfaces of the upper insulating film 160, the side surfaces of the capping insulating film 150, the side surfaces of the cell insulating film 155, and the side surfaces of the second lower insulating film 130 may be coplanar. The upper surface of the peripheral insulating film 180 may be substantially coplanar with the upper surface of the upper insulating film 160.

The peripheral insulating film 180 may include a different material from the cell insulating film 155. The peripheral insulating film 180 may include an insulating material with a smaller dielectric constant (k) than the cell insulating film 155. The peripheral insulating film 180 may include a different material from the upper insulating film 160 and may include an insulating material with a smaller dielectric constant (k) than the upper insulating film 160. The peripheral insulating film 180 may include, for example, silicon oxide, silicon nitride, and/or silicon oxynitride. For example, the peripheral insulating film 180 may include an insulating material with a dielectric constant (k) of about 2.5 or less, or about 2.0 or less, and may include, for example, porous SiOC.

The interlayer insulating film 190 may be disposed on the upper insulating film 160 over the cell region CR and the interface region IR, and on the peripheral insulating film 180 over the peripheral region PR. The interlayer insulating film 190 may include, for example, silicon oxide, silicon nitride, and/or silicon oxynitride.

The cell conductive lines 196 may be disposed on the cell region CR of the substrate 100. The cell conductive lines 196 may extend in the second direction Y and may be spaced apart from each other in the first direction X. The cell conductive lines 196 may have a line shape extending in the second direction Y.

The cell conductive lines 196 may be electrically connected to the first information storage patterns DS1. The cell conductive lines 196 may penetrate or extend into the upper insulating film 160 to be connected to the first information storage patterns DS1. The cell conductive lines 196 may contact the upper electrodes TE of the first information storage patterns DS1. The cell conductive lines 196 may include a conductive material, for example, a metal such as Cu.

In some embodiments, the second information storage patterns DS2 may be electrically insulated from the lower electrode contacts 140 and may also be electrically insulated from the cell conductive lines 196. The lower electrode contacts 140 may not be disposed between the second information storage patterns DS2 and the substrate 100. The cell conductive lines 196 may not be disposed on (e.g., is free from overlap in the Z direction) the second information storage patterns DS2.

In some embodiments, the second information storage patterns DS2 may be electrically connected to the lower electrode contacts 140 and electrically insulated from the cell conductive lines 196. The lower electrode contacts 140 may be disposed between the second information storage patterns DS2 and the substrate 100, and the cell conductive lines 196 may not be disposed on (e.g., is free from overlap in the Z direction) the second information storage patterns DS2. In some embodiments, the second information storage patterns DS2 may be electrically insulated from the lower electrode contacts 140 and electrically connected to the cell conductive lines 196. The lower electrode contacts 140 may not be disposed between the second information storage patterns DS2 and the substrate 100, and the cell conductive lines 196 may be disposed on the second information storage patterns DS2. In some embodiments, the second information storage patterns DS2 may be electrically insulated from both the lower electrode contacts 140 and the cell conductive lines 196. The lower electrode contacts 140 may not be disposed between the second information storage patterns DS2 and the substrate 100, and the cell conductive lines 196 may not be disposed on the second information storage patterns DS2.

The peripheral conductive lines 194 may be disposed on the peripheral region PR of the substrate 100. The peripheral conductive lines 194 may be disposed within the interlayer insulating film 190 and the peripheral insulating film 180 over the peripheral region PR. The upper surfaces of the peripheral conductive lines 194 may not be covered or overlapped by the interlayer insulating film 190 and may be at least partially exposed.

The peripheral conductive contacts 192 may be disposed on the peripheral region PR of the substrate 100. The peripheral conductive contacts 192 may be disposed below the peripheral conductive lines 194. The peripheral conductive contacts 192 may be electrically connected to the peripheral conductive lines 194. There may be no boundary between the peripheral conductive contacts 192 and the peripheral conductive lines 194. The peripheral conductive contacts 192 may penetrate or extend into the lower portion of the peripheral insulating film 180 and the first lower insulating film 120. The upper surfaces of the peripheral conductive lines 194 may be substantially coplanar with the upper surface of the interlayer insulating film 190. The upper surfaces of the peripheral conductive contacts 192 may be disposed within the peripheral insulating film 180.

The peripheral conductive contacts 192 may be electrically connected to the wiring lines 108. The peripheral conductive lines 194 may be electrically connected to terminals (e.g., source terminals, drain terminals, or gate terminals) of the peripheral transistors through the peripheral conductive contacts 192 and the wiring lines 108.

The peripheral conductive lines 194 and the peripheral conductive contacts 192 may include a conductive material, for example, a metal such as Cu. Each of the peripheral conductive lines 194 and the peripheral conductive contacts 192 may include the same material.

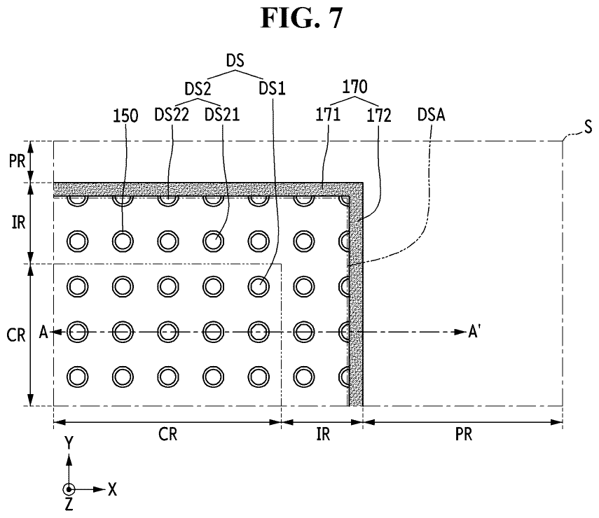

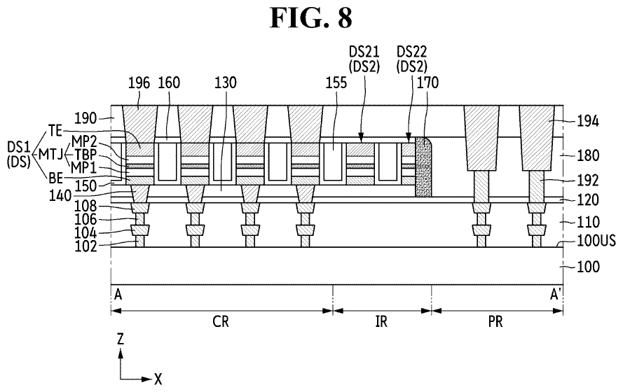

FIG. 5 is a diagram illustrating a magnetic memory device according to some embodiments. FIG. 6 is a cross-sectional view taken along line A-A′ of FIG. 5. For reference, FIG. 5 is an enlarged view of area S of FIG. 2. For convenience of explanation, the differences from what has been described with reference to FIGS. 1 through 4 will be focused on.

Referring to FIGS. 5 and 6, the magnetic memory device according to some embodiments may further include a spacer 170.

The spacer 170 may surround or extend around an array DSA. The spacer 170 may extend along the perimeter of the array DSA. The spacer 170 may include first extension parts 171 extending in a first direction X and second extension parts 172 extending in a second direction Y. The first extension parts 171 may have a line shape extending in the first direction X. The second extension parts 172 may have a line shape extending in the second direction Y. The spacer 170 may include two first extension parts 171 spaced apart in the second direction Y and two second extension parts 172 spaced apart in the first direction X.

In some embodiments, the spacer 170 may be spaced apart from second information storage patterns DS2. The spacer 170 may be spaced apart from the second information storage patterns DS2 located at the outermost part (e.g., an edge) of the array DSA (or at the part of the array DSA closest to a peripheral region PR).

In some embodiments, the spacer 170 may be disposed on the peripheral region PR of a substrate 100. The array DSA may be disposed across the entire cell region CR and the interface region IR of the substrate 100. The information storage patterns DS may be arranged in the first and second directions X and Y across an entire cell region CR and an interface region IR of the substrate 100.

The spacer 170 may be disposed on a first lower insulating film 120. The spacer 170 may be disposed on the first lower insulating film 120 over the peripheral region PR of the substrate 100. The spacer 170 may be disposed on the side surfaces of an upper insulating film 160, the side surfaces of a cell insulating film 155, the side surfaces of a capping insulating film 150, and the side surfaces of a second lower insulating film 130. The spacer 170 may be interposed between the upper insulating film 160, the cell insulating film 155, the capping insulating film 150, and the second lower insulating film 130, and a peripheral insulating film 180.

The spacer 170 may include a different material from the upper insulating film 160. For example, the spacer 170 may include an oxide and/or silicon oxide.

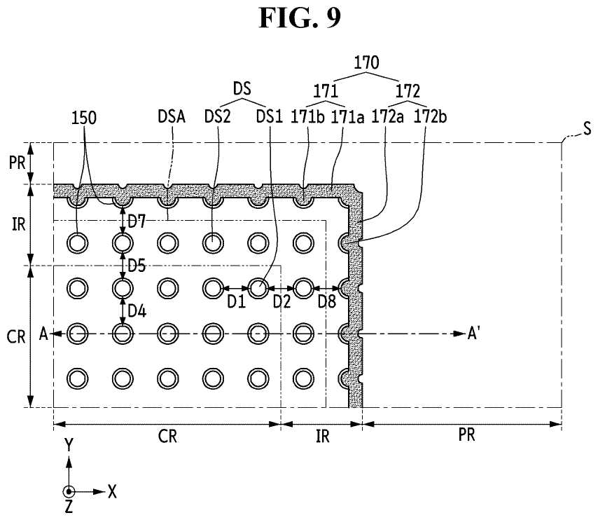

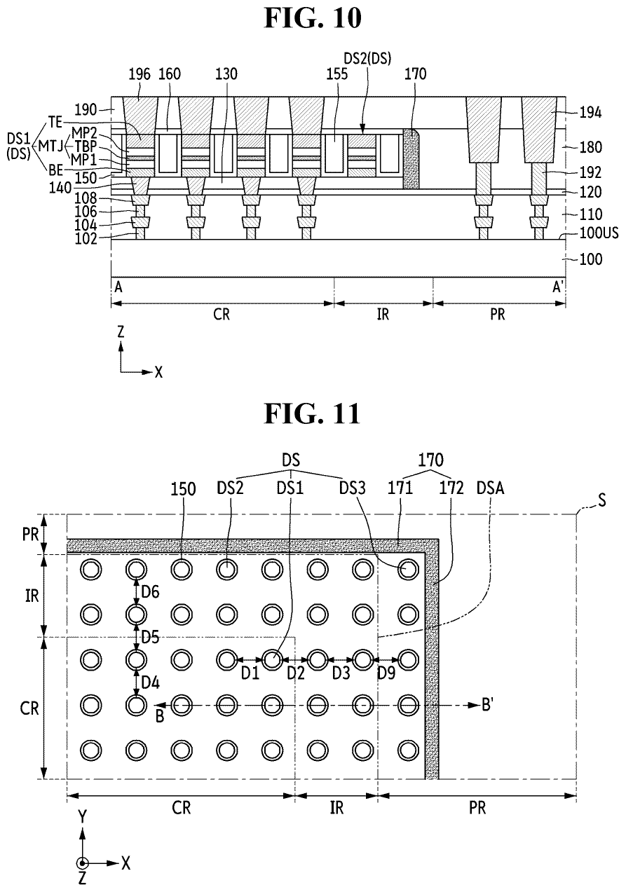

FIG. 7 is a diagram illustrating a magnetic memory device according to some embodiments. FIG. 8 is a cross-sectional view taken along line A-A′ of FIG. 7. For reference, FIG. 7 is an enlarged view of area S of FIG. 2. For convenience of explanation, the differences from what has been described with reference to FIGS. 1 through 6 will be focused on.

Referring to FIGS. 7 and 8, in the magnetic memory device according to some embodiments, at least some second information storage patterns DS2 may have a partially cut circular shape from a planar perspective.

For example, the second information storage patterns DS2 may include first sub-information storage patterns DS21 and second sub-information storage patterns DS22. From a planar perspective, the first sub-information storage patterns DS21 may have a circular shape, and the second sub-information storage patterns DS22 may have a partially cut circular shape (e.g., a semicircular shape or a shape corresponding to a segment of a circle).

For example, part of an interface region IR adjacent to a cell region CR in a first direction X and part of the interface region IR adjacent to the cell region CR in a second direction Y may both include the first sub-information storage patterns DS21 and the second sub-information storage patterns DS22. The maximum width, in the first direction X, of the second sub-information storage patterns DS22 in the part of the interface region IR adjacent to the cell region CR in the first direction X may be smaller or less than the width, in the first direction X, of the first sub-information storage patterns DS21 in the part of the interface region IR adjacent to the cell region CR in the second direction X. The maximum width, in the second direction Y, of the second sub-information storage patterns DS22 in the part of the interface region IR adjacent to the cell region CR in the second direction Y may be smaller or less than the width, in the second direction Y, of the first sub-information storage patterns DS21 in the part of the interface region IR adjacent to the cell region CR in the second direction DR2.

The maximum width, in the first direction X, of the second sub-information storage patterns DS22 in the part of the interface region IR adjacent to the cell region CR in the first direction X may be the same as, or different from, the maximum width, in the second direction Y, of the second sub-information storage patterns DS22 in the part of the interface region IR adjacent to the cell region CR in the second direction Y.

In another example, one of the part of the interface region IR adjacent to the cell region CR in the first direction X and the part of the interface region IR adjacent to the cell region CR in the second direction Y may include the first sub-information storage patterns DS21 and the second sub-information storage patterns DS22, and the other part of the interface region IR may include only the first sub-information storage patterns DS21.

The second sub-information storage patterns DS22 may be disposed at the outermost part (e.g., an edge) of the array DSA. The second sub-information storage patterns DS22 may be closest to a peripheral region PR.

The peripheral insulating film 180 may be disposed on the side surfaces of a first lower insulating film 120, a second lower insulating film 130, the second sub-information storage patterns DS22, and an upper insulating film 160. The side surfaces of the first lower insulating film 120, the second lower insulating film 130, the second sub-information storage patterns DS22, and the upper insulating film 160 may be coplanar.

In another example, each of the second information storage patterns DS2 may have a partially cut circular shape (e.g., a semicircular shape or a shape corresponding to a segment of a circle) from a planar perspective. That is, the second information storage patterns DS2 may include only the second sub-information storage patterns DS22.

The second sub-information storage patterns DS22 may be in contact with a spacer 170. The second sub-information storage patterns DS22 may be partially cut by the spacer 170.

In some embodiments, the spacer 170 may be disposed on the interface region IR of a substrate 100. In some embodiments, the spacer 170 may be disposed on both the interface region IR and the peripheral region PR of the substrate 100. That is, the spacer 170 may be formed across the interface region IR and the peripheral region PR of the substrate 100.

In some embodiments, the spacer 170 may be omitted. When there is no spacer 170, the peripheral insulating film 180 may contact the side surfaces of the first lower insulating film 120, the second lower insulating film 130, the second sub-information storage patterns DS22, and the upper insulating film 160.

In some embodiments, the part of the interface region IR adjacent to the cell region CR in the first direction X may include the second sub-information storage patterns DS21, and the part of the interface region IR adjacent to the cell region CR in the second direction Y may include both the first sub-information storage patterns DS21 and the second sub-information storage patterns DS22.

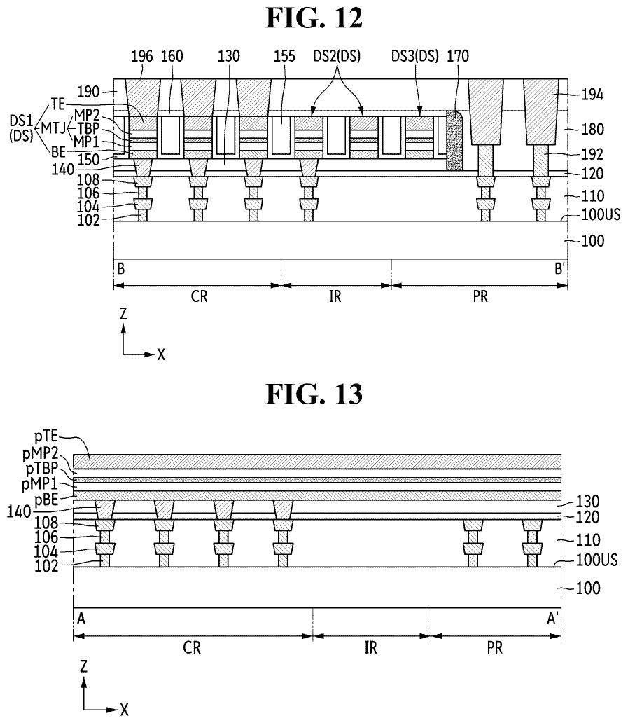

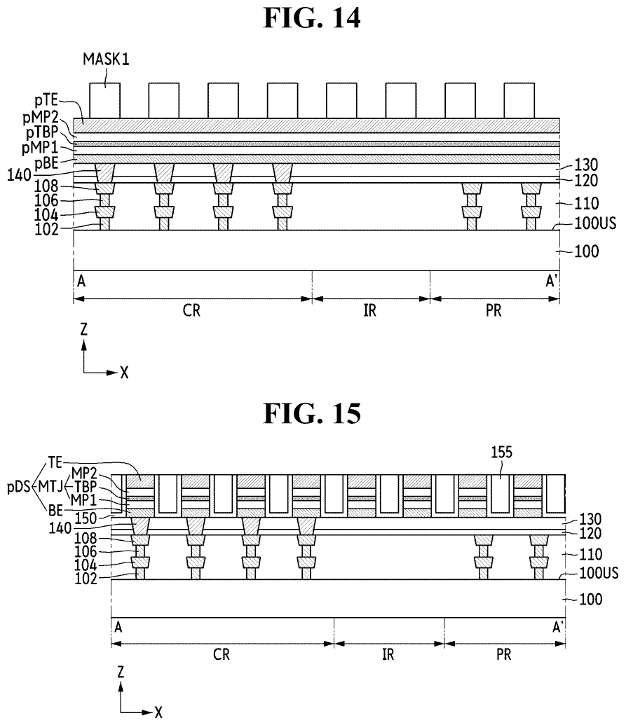

FIG. 9 is a diagram illustrating a magnetic memory device according to some embodiments. FIG. 10 is a cross-sectional view taken along line A-A′ of FIG. 9. For reference, FIG. 9 is an enlarged view of area S of FIG. 2. For convenience of explanation, the differences from what has been described with reference to FIGS. 1 through 8 will be focused on.

Referring to FIGS. 9 and 10, in the magnetic memory device according to some embodiments, a spacer 170 may include convex portions (171b and 172b) protruding or extending toward an array DSA.

For example, a first extension part 171 may include a first portion 171a extending in a first direction X and first convex portions 171b protruding or extending toward the array DSA. The two side surfaces of each of the first convex portions 171b in a second direction Y may be convex toward the array DSA. The first convex portions 171b may be spaced apart from information storage patterns DS. The first convex portions 171a may be spaced apart from second information storage patterns DS2 by a seventh distance D7 in the second direction Y.

The seventh distance D7 may be substantially the same as a fourth distance D4 and a fifth distance D5. A second extension part 172 may include a second portion 172a extending in the second direction Y and second convex portions 172b protruding or extending toward the array DSA. The two side surfaces of each of the second convex portions 172b in the first direction X may be convex toward the array DSA. The second convex portions 172b may be spaced apart from the information storage patterns DS. The second convex portions 172a may be spaced apart from the second information storage patterns DS2 by an eighth distance D8 in the first direction X. The eighth distance D8 may be substantially the same as a first distance D1 and a second distance D2.

In another example, either one of the first extension part 171 or the second extension part 172 may include the convex portions (171b and 172b) protruding or extending toward the array DSA, while the other may not include the convex portions (171b and 172b) protruding or extending toward the array DSA.

A capping insulating film 150 may be disposed on the side surfaces of the convex portions (171b and 172b) of the spacer 170 that face the array DSA. The capping insulating film 150 may extend along the side surfaces of the convex portions (171b and 172b) of the spacer 170 that face the array DSA. The convex portions (171b and 172b) of the spacer 170 may be interposed between a cell insulating film 155 and a peripheral insulating film 180. The convex portions (171b and 172b) of the spacer 170 may contact the cell insulating film 155. The convex portions (171b and 172b) of the spacer 170 may be disposed on the side surfaces of an upper insulating film 160, the side surfaces of the capping insulating film 150, and the side surfaces of a second lower insulating film 130.

The capping insulating film 150 may not be disposed on the side surfaces of the first and second portions 171a and 172a of the spacer 170 that face the array DSA. The first and second portions 171a and 172a of the spacer 170 may be interposed between the cell insulating film 155 and the peripheral insulating film 180. The first and second portions 171a and 172a of the spacer 170 may be disposed on the side surfaces of the upper insulating film 160, the side surfaces of the cell insulating film 155, the side surfaces of the capping insulating film 150, and the side surfaces of the second lower insulating film 130. The first and second portions 171a and 172a of the spacer 170 may be interposed between the upper insulating film 160, the cell insulating film 155, the capping insulating film 150, the second lower insulating film 130, and the peripheral insulating film 180.

In some embodiments, the spacer 170 may be disposed on an interface region IR of a substrate 100. In some embodiments, the information storage patterns DS may be arranged in the first and second directions X and Y across an entire cell region CR and the interface region IR of the substrate 100, and the spacer 170 may be spaced apart from the information storage patterns DS and disposed on the peripheral region PR of the substrate 100.

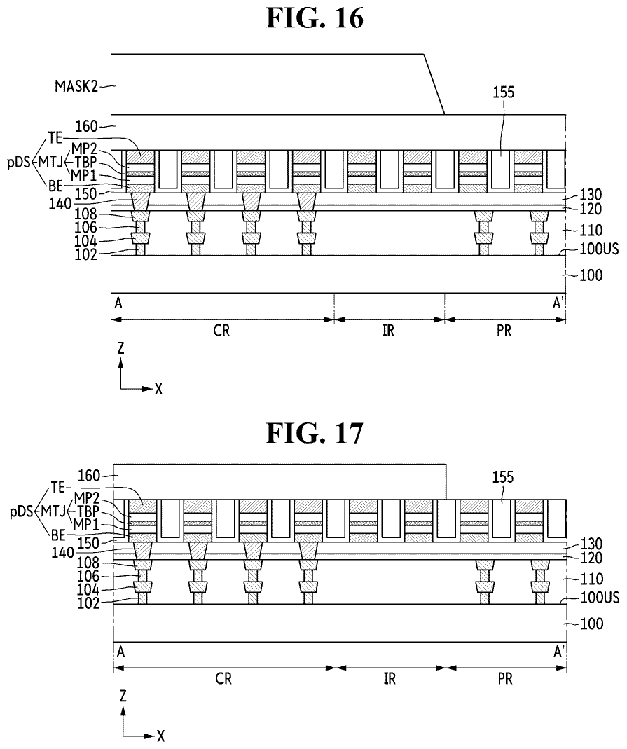

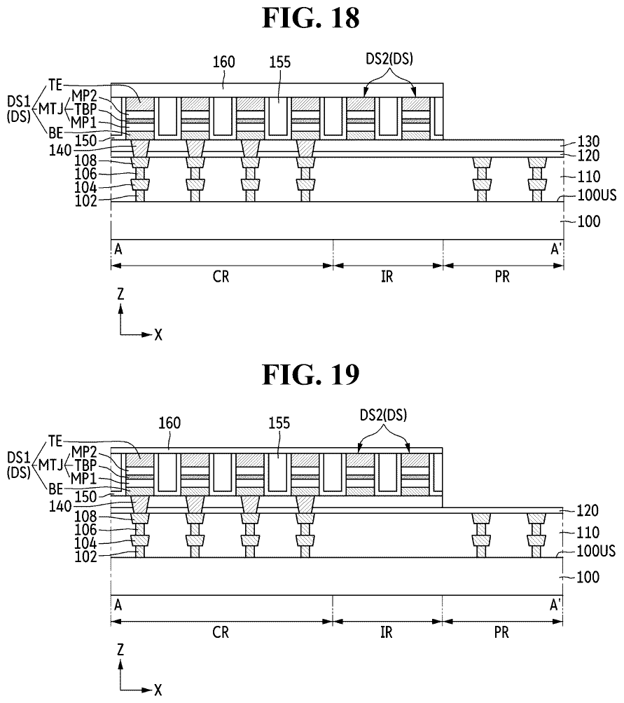

FIG. 11 is a diagram illustrating a magnetic memory device according to some embodiments. FIG. 12 is a cross-sectional view taken along line B-B′ of FIG. 11. For reference, FIG. 11 is an enlarged view of area S of FIG. 2. For convenience of explanation, the differences from what has been described with reference to FIGS. 1 through 10 will be focused on.

Referring to FIGS. 11 and 12, in the magnetic memory device according to some embodiments, an array DSA may be disposed on part of a cell region CR, an interface region IR, and a peripheral region PR of a substrate 100. The array DSA may be disposed on part of the peripheral region PR adjacent to the interface region IR.

Information storage patterns DS may further include third information storage patterns DS3 disposed on the peripheral region PR of the substrate 100. The third information storage patterns DS3 may have the same structure as second information storage patterns DS2. The third information storage patterns DS3 may include lower electrodes BE, magnetic tunnel junction patterns MTJ, and upper electrodes TE. The magnetic tunnel junction patterns MTJ may be disposed between the lower electrodes BE and the upper electrodes TE. The third information storage patterns DS3 may also be referred to as dummy information storage patterns.

The third information storage patterns DS3 may be electrically insulated from lower electrode contacts 140 and may also be electrically insulated from cell conductive lines 196. The lower electrode contacts 140 may not be disposed between the third information storage patterns DS3 and the substrate 100. The cell conductive lines 196 may not be disposed on the second information storage patterns DS2.

In some embodiments, the third information storage patterns DS3 may be disposed on part of the peripheral region PR adjacent to the interface region IR in a first direction X. The third information storage patterns DS3 may be disposed on at least one of the part of the peripheral region PR adjacent to the interface region IR in the first direction X and part of the peripheral region PR adjacent to the interface region IR in a second direction Y. When the third information storage patterns DS3 are disposed on the part of the peripheral region PR adjacent to the interface region IR in the first direction X, the third information storage patterns DS3 may be arranged along at least one column extending in the second direction Y. When the third information storage pattern DS3 is disposed on the part of the peripheral region PR adjacent to the interface region IR in the second direction Y, the third information storage patterns DS3 may be arranged along at least one row extending in the first direction X.

For example, in the part of the peripheral region PR adjacent to the interface region IR in the first direction X, third information storage patterns DS3 that are spaced apart from each other along a single column may be disposed. The third information storage patterns DS3 may be spaced apart from the second information storage patterns DS2 by a ninth distance D9 in the first direction X. The ninth distance D9 may be substantially the same as a first distance D1, a second distance D2, and a third distance D3.

In some embodiments, a spacer 170 may be spaced apart from the third information storage patterns DS3.

In some embodiments, at least some of the third information storage patterns DS3 may have a partially cut circular shape from a planar perspective, similar to the second information storage patterns DS2 of FIG. 7. The third information storage patterns DS3 disposed at the outermost part (e.g., an edge) of the array DSA may have a partially cut circular shape from a planar perspective. The spacer 170 surrounding or extending around the array DSA and some of the third information storage patterns DS3 disposed at the outermost part of the array DSA may be cut by the spacer 170. The spacer 170 may be in contact with the third information storage patterns DS3 disposed at the outermost part of the array DSA.

In some embodiments, the spacer 170 may include convex portions protruding or extending toward the array DSA, similar to the spacer 170 illustrated in FIG. 9.

In some embodiments, there may be no spacer 170.

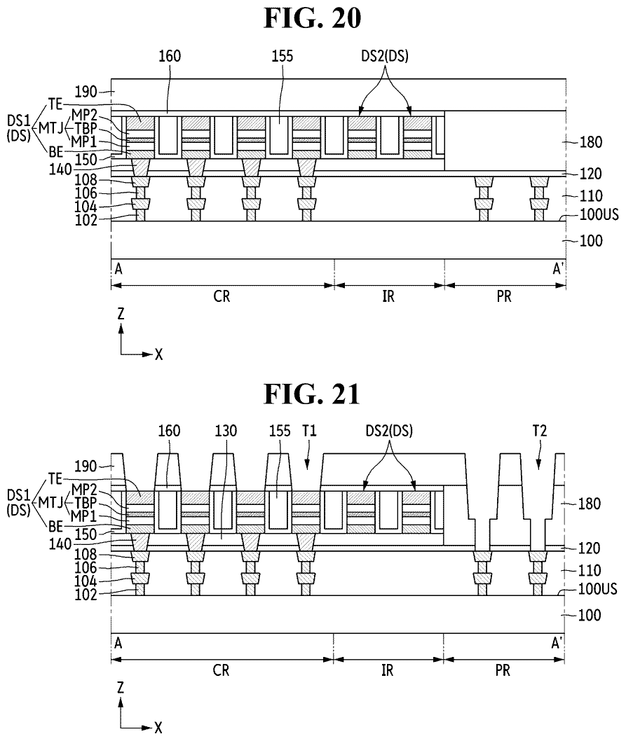

FIGS. 13 through 21 are diagrams illustrating a method for manufacturing a magnetic memory device according to some embodiments. For convenience of explanation, the differences from what has been described with reference to FIGS. 1 through 12 will be focused on.

Referring to FIG. 13, a substrate 100, which includes a cell region CR, an interface region IR, and a peripheral region PR, may be provided.

Selection elements (“SE” in FIG. 1) and peripheral transistors may be formed on an upper surface 100US of the substrate 100. A wiring structure (102, 104, 106, and 108) may be formed on the selection elements and the peripheral transistors. The wiring structure (102, 104, 106, and 108) may include wiring lines (104 and 108), which are vertically spaced apart from the substrate 100 (e.g., in a third direction Z), and wiring contacts (102 and 106) connected to the wiring lines (104 and 108). The wiring lines (104 and 108) may be electrically connected to terminals (e.g., source terminals, drain terminals, or gate terminals) of the selection elements or terminals (e.g., source terminals, drain terminals, or gate terminals) of the peripheral transistors through the respective wiring contacts (102 and 106).

A wiring insulating film 110 may be formed on the substrate 100. The wiring insulating film 110 may cover or at least partially overlap the wiring structure (102, 104, 106, and 108).

The wiring insulating film 110 may at least partially expose the upper surfaces of uppermost wiring lines 108.

A first lower insulating film 120 may be formed on the wiring insulating film 110. The first lower insulating film 120 may be formed on the wiring insulating film 110 over the cell region CR, the interface region IR, and the peripheral region PR. The first lower insulating film 120 may cover or at least partially overlap the exposed upper surfaces of the uppermost wiring lines 108.

A lower insulating film 130 may be formed on the first lower insulating film 120. The lower insulating film 130 may be formed on the first lower insulating film 120 over the cell region CR, the interface region IR, and the peripheral region PR.

Lower electrode contacts 140 may be formed within the lower insulating film 130 over the cell region CR. The lower electrode contacts 140 may penetrate or extend into the lower insulating film 130 and the first lower insulating film 120 over the cell region CR and may be electrically connected to the uppermost wiring lines 108.

Forming the lower electrode contacts 140 may involve, for example, forming lower contact holes that penetrate or extend into the lower insulating film 130 and the first lower insulating film 120 over the cell region CR, forming a lower contact film that fills or is in the lower contact holes on the lower insulating film 130, and planarizing the lower contact film until the upper surface of the lower insulating film 130 is exposed. As a result of this planarization process, the lower electrode contacts 140 that fill or are in the lower contact holes may be formed.

A preliminary lower electrode pBE, a preliminary first magnetic pattern pMP1, a preliminary tunnel barrier pattern pTBP, a preliminary second magnetic pattern pMP2, and a preliminary upper electrode pTE may be sequentially formed on the lower insulating film 130 and the lower electrode contacts 140. The preliminary lower electrode pBE, the preliminary first magnetic pattern pMP1, the preliminary tunnel barrier pattern pTBP, the preliminary second magnetic pattern pMP2, and the preliminary upper electrode pTE may be formed on the lower insulating film 130 and the lower electrode contacts 140 over the cell region CR, the interface region IR, and the peripheral region PR. The preliminary first magnetic pattern pMP1, the preliminary tunnel barrier pattern pTBP, and the preliminary second magnetic pattern pMP2 may also be referred to as preliminary magnetic tunnel junction patterns.

Each of the preliminary first magnetic pattern pMP1, the preliminary tunnel barrier pattern pTBP, and the preliminary second magnetic pattern pMP2 may be formed by, for example, sputtering, chemical vapor deposition (CVD), or atomic layer deposition (ALD).

The preliminary lower electrode pBE may include, for example, a conductive metal nitride such as titanium nitride or tantalum nitride. For example, the preliminary first magnetic pattern pMP1 and the preliminary second magnetic pattern pMP2 may each include at least one of the aforementioned intrinsic perpendicular magnetic material or extrinsic perpendicular magnetic material. Alternatively, the preliminary first magnetic pattern pMP1 and the preliminary second magnetic pattern pMP2 may each include the aforementioned ferromagnetic material. The preliminary tunnel barrier pattern pTBP may include, for example, at least one of a magnesium oxide film, a titanium oxide film, an aluminum oxide film, a magnesium-zinc oxide film, or a magnesium-boron oxide film. The preliminary upper electrode pTE may include at least one of a metal (e.g., Ta, W, Ru, Ir) or a conductive metal nitride (e.g., TiN).

Referring to FIG. 14, a first mask pattern MASK1 may be formed on the preliminary upper electrode pTE. The first mask pattern MASK1 may define the area in which to form an array DSA. The first mask pattern MASK1 may include, for example, an oxide.

Referring to FIGS. 14 and 15, using the first mask pattern MASK1 as an etch mask, the preliminary upper electrode pTE, the preliminary second magnetic pattern pMP2, the preliminary tunnel barrier pattern pTBP, the preliminary first magnetic pattern pMP1, and the preliminary lower electrode pBE may be etched. Accordingly, preliminary information storage patterns pDS, which include upper electrodes TE, second magnetic patterns MP2, tunnel barrier patterns TBP, first magnetic patterns MP1, and lower electrodes BE, may be formed. The preliminary information storage patterns pDS may be arranged in the first and second directions X and Y over the cell region CR, the interface region IR, and the peripheral region PR on the substrate 100.

The lower electrodes BE may be connected to the lower electrode contacts 140. The magnetic tunnel junction patterns MTJ may include the first magnetic patterns MP1, the tunnel barrier patterns TBP, and the second magnetic patterns MP2. The upper electrodes TE may be connected to the second magnetic patterns MP2. The magnetic tunnel junction patterns MTJ are formed over the cell region CR, the interface region IR, and the peripheral region PR.

Thereafter, the first mask pattern MASK1 may be removed.

For example, the preliminary upper electrode pTE may be etched using the first mask pattern MASK1 as an etch mask, and then the first mask pattern MASK1 may be removed.

Thereafter, the preliminary upper electrode pTE, the preliminary second magnetic pattern pMP2, the preliminary tunnel barrier pattern pTBP, the preliminary first magnetic pattern pMP1, and the preliminary lower electrode pBE may be etched by, for example, ion beam etching using an ion beam. The ion beam may include inert ions. Through this etching process, the upper portion of the second lower insulating film 130 on both sides of the magnetic tunnel junction patterns MTJ may be recessed. The lowest surface of the second lower insulating film 130 may be positioned lower than the upper surfaces of the lower electrode contacts 140 relative to the substrate 100 and in the Z direction.

Thereafter, a capping insulating film 150 extending along the side surfaces of the second lower insulating film 130 and the lower electrodes BE and a cell insulating film 155 filling or in the spaces between the lower electrodes BE on the capping insulating film 150 may be formed.

For example, the capping insulating film 150 may be formed along the upper surfaces and side surfaces of the second lower insulating film 130 and the preliminary information storage patterns pDS. The capping insulating film 150 may be conformally formed along the upper surfaces and side surfaces of the second lower insulating film 130 and the preliminary information storage patterns pDS. Thereafter, a cell insulating film 155 covering or overlapping the capping insulating film 150 may be formed. The cell insulating film 155 may fill or be in the spaces between the preliminary information storage patterns pDS on the capping insulating film 150. The cell insulating film 155 may be formed by, for example, ALD. Thereafter, portions of the cell insulating film 155, portions of the capping insulating film 150, and/or portions of the upper electrode TE may be etched. The upper electrode TE and the capping insulating film 150 may be exposed. Portions of the cell insulating film 155, portions of the capping insulating film 150, and/or portions of the upper electrodes TE may be etched using a planarization process.

The upper surface of the cell insulating film 155, the upper surface of the capping insulating film 150, and the upper surfaces of the upper electrodes TE may form a substantially coplanar surface.

Referring to FIG. 16, an upper insulating film 160 may be formed on the cell insulating film 155, the capping insulating film 150, and the upper electrodes TE. The upper insulating film 160 may cover or at least partially overlap the cell insulating film 155, the capping insulating film 150, and the upper electrodes TE. The thickness of the upper insulating film 160 in the third direction Z may be determined in consideration of subsequent etching processes that will be described later with reference to FIGS. 18 and 19.

Thereafter, a second mask pattern MASK2 may be formed on the upper insulating film 160. The second mask pattern MASK2 may be formed by, for example, forming a photoresist film over the upper insulating film 160 and then performing a photolithography process on the photoresist film. The photolithography process may be performed using an exposure process with low resolution that uses long wavelengths. For example, the photolithography process may be performed using a KrF photolithography process with a wavelength of 248 nm.

The second mask pattern MASK2 may cover the cell region CR. The second mask pattern MASK2 may expose at least a portion of the peripheral region PR.

Depending on the area where the second mask pattern MASK2 is disposed, the region in which to form an array DSA may be determined. For example, if the second mask pattern MASK2 exposes the peripheral region PR, the array DSA may be formed on the cell region CR and the interface region IR of the substrate 100, as illustrated in FIG. 3. As another example, if the second mask pattern MASK2 exposes part of the peripheral region PR and part of the interface region IR adjacent to the peripheral region PR, the array DSA may be formed on part of the cell region CR and part of the interface region IR of the substrate 100, as illustrated in FIG. 7. As a further example, if the second mask pattern MASK2 exposes part of the interface region IR that overlaps in the vertical direction Z with some of the preliminary information storage patterns pDS at the outermost part of the interface region IR, second sub-information storage patterns DS21 may be formed, as illustrated in FIG. 7.

Referring to FIGS. 16 and 17, using the second mask pattern MASK2 as an etch mask, the upper insulating film 160 may be etched. The upper insulating film 160 on the peripheral region PR may be etched. Consequently, the preliminary information storage patterns pDS, the capping insulating film 150, and the cell insulating film 155 on the peripheral region PR may be exposed.

Thereafter, the second mask pattern MASK2 may be removed.

Referring to FIGS. 17 and 18, the preliminary information storage patterns pDS, the capping insulating film 150, and the cell insulating film 155 on the peripheral region PR exposed by the upper insulating film 160 may be etched. As a result, an array DSA including the first information storage patterns DS1 on the cell region CR and the second information storage patterns DS2 on the interface region IR may be formed, as illustrated in FIG. 3. At this point, portions of the upper insulating film 160 on the cell region CR and the interface region IR may also be etched. Consequently, the second lower insulating film 130 on the peripheral region PR may be exposed. The first information storage patterns DS1 are the preliminary information storage patterns pDS formed in the cell region CR, and the second information storage patterns DS2 are the preliminary information storage patterns pDS formed in the interface region IR.

For example, the upper insulating film 160, the information storage patterns DS on the peripheral region PR exposed by the upper insulating film 160, the capping insulating film 150, and the cell insulating film 155 may be etched using an ion beam etching process. The ion beam etching process may simultaneously etch the upper insulating film 160, the information storage patterns DS on the peripheral region PR exposed by the upper insulating film 160, the capping insulating film 150, and the cell insulating film 155 without selectivity.

Referring to FIGS. 18 and 19, the second lower insulating film 130 on the peripheral region PR may be etched. As a result, the first lower insulating film 120 on the peripheral region PR may be exposed. At this time, the portions of the upper insulating film 160 on the cell region CR and the interface region IR may also be etched.

Referring to FIG. 20, a peripheral insulating film 180 may be formed on the first lower insulating film 120 on the peripheral region PR. The upper surface of the peripheral insulating film 180 may be substantially coplanar with the upper surfaces of the portions of the upper insulating film 160 on the cell region CR and the interface region IR.

Thereafter, an interlayer insulating film 190 may be formed on the upper insulating film 160 and the peripheral insulating film 180. The upper surfaces of the portions of the interlayer insulating film 190 on the cell region CR, the interface region IR, and the peripheral region PR may be substantially coplanar.

Referring to FIG. 21, first trenches T1 may be formed on the cell region CR. The first trenches T1 may penetrate or extend into the interlayer insulating film 190 and the upper insulating film 160 on the cell region CR. The first trenches T1 may at least partially expose the upper surfaces of the first information storage patterns DS1. The first trenches T1 may at least partially expose the upper electrodes TE of the first information storage patterns DS1.

Second trenches T2 may be formed on the peripheral region PR. The second trenches T2 may penetrate or extend into the interlayer insulating film 190 and the peripheral insulating film 180 on the peripheral region PR. The second trenches T2 may at least partially expose the wiring lines 108 on the peripheral region PR. In a direction parallel to the upper surface 100US of the substrate 100 (e.g., the X direction), the upper width of the second trenches T2 may be larger or greater than the lower width of the second trenches T2. The sidewalls of the second trenches T2 may have a step difference within the peripheral insulating film 180.

Referring to FIGS. 21 and 4, cell conductive lines 196 filling or in the first trenches T1 may be formed, and peripheral conductive contacts 192 and peripheral conductive lines 194 filling or in the second trenches T2 may be formed.

The method for manufacturing a magnetic memory device according to some embodiments forms the preliminary upper electrode pTE on the cell region CR, the interface region IR, and the peripheral region PR, forms the preliminary information storage patterns pDS, and then removes the preliminary information storage patterns pDS on the peripheral region PR, thereby forming information storage patterns DS on the cell region CR. Therefore, no mask pattern is needed compared to the case of forming a mask pattern that exposes the cell region CR and the interface region IR while covering or overlapping the peripheral region PR and then forming the information storage patterns DS on the cell region CR. Moreover, in the method for manufacturing a magnetic memory device according to some embodiments, since the upper surface of the preliminary upper electrode pTE is coplanar throughout the cell region CR, the interface region IR, and the peripheral region PR, the process margin in the planarization process may be larger compared to when the upper surface of the preliminary upper electrode pTE is stepped in the cell region CR, the interface region IR, and the peripheral region PR.

Additionally, due to the sufficient thickness of the second lower insulating film 130 in the peripheral region PR, the wiring structure (102, 104, 106, and 108) is not exposed when the second lower insulating film 130 in the peripheral region PR is removed, as illustrated in FIG. 19. Thus, a more reliable magnetic memory device can be fabricated.

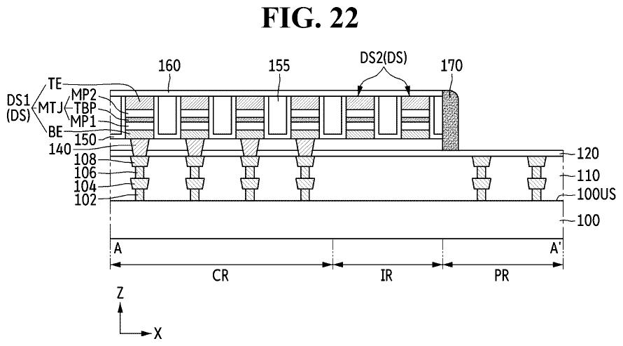

FIG. 22 is a diagram illustrating a method for manufacturing a magnetic memory device according to some embodiments. For convenience of explanation, the differences from what has been described with reference to FIGS. 1 through 21 will be focused on. For reference, FIG. 22 is a diagram illustrating steps subsequent to those illustrated in FIG. 18.

Referring to FIG. 22, a spacer 170 surrounding or extending around an array (“DSA” in FIG. 3) may be formed. The spacer 170 may be formed on a first lower insulating film 120.

Referring to FIG. 6, a peripheral insulating film 180 may be formed on the first lower insulating film 120 on a peripheral region PR. The peripheral insulating film 180 may cover or at least partially overlap the side surfaces of the spacer 170.

Thereafter, an interlayer insulating film 190 may be formed on the upper insulating film 160 and the peripheral insulating film 180. Cell conductive lines 196 penetrating or extending into the interlayer insulating film 190 and the upper insulating film 160 may be formed on a cell region CR. Peripheral conductive contacts 192 and peripheral conductive lines 194 penetrating or extending into the interlayer insulating film 190 and the peripheral insulating film 180 may be formed on the peripheral region PR.

Although the embodiments of the present disclosure have been described with reference to the attached drawings, the present disclosure is not limited to these embodiments and may be manufactured in various other forms. It will be understood by those skilled in the art that the disclosure can be embodied in other specific forms. Therefore, the embodiments described above should be understood as illustrative and not restrictive in all respects as defined by the appended claims.

What is claimed is:

1. A magnetic memory device comprising:
a substrate comprising a cell region, a peripheral region extending around the cell region, and an interface region between the cell region and the peripheral region;
a lower insulating film on the cell region and the peripheral region of the substrate;
lower electrode contacts extending into the lower insulating film;
information storage patterns that are spaced apart from each other in a first direction and are on the lower insulating film;
a cell insulating film that is between adjacent ones of the information storage patterns and is on the lower insulating film;
an upper insulating film that is on an upper surface of the cell insulating film and are on upper surfaces of the information storage patterns and is free from overlap with the peripheral region of the substrate in a second direction that is perpendicular to the first direction; and
a peripheral insulating film on the peripheral region of the substrate,
wherein:
the information storage patterns comprise magnetic tunnel junction patterns, first information storage patterns on the cell region of the substrate, and second information storage patterns on the interface region of the substrate,
the first information storage patterns are electrically connected to respective ones of the lower electrode contacts, and
the second information storage patterns are electrically insulated from the lower electrode contacts.

2. The magnetic memory device of claim 1, wherein a width of one of the first information storage patterns in the first direction is equal to a width of one of the second information storage patterns in the first direction.

3. The magnetic memory device of claim 1, wherein a width of one of the second information storage patterns along an edge of the interface region in the first direction is less than a width of one of the first information storage patterns in the first direction.

4. The magnetic memory device of claim 3, further comprising:
a spacer that extends around the cell insulating film and the upper insulating film.

5. The magnetic memory device of claim 4, further comprising:
a capping insulating film that is between the information storage patterns and the cell insulating film, is between the lower insulating film and the cell insulating film, and is between the cell insulating film and the spacer.

6. The magnetic memory device of claim 4, wherein the upper insulating film comprises a different material from the spacer.

7. A method for manufacturing a magnetic memory device, comprising:
providing a substrate comprising a cell region, a peripheral region, and an interface region between the cell region and the peripheral region;
forming preliminary information storage patterns on the cell region, the peripheral region, and the interface region of the substrate, wherein the preliminary information storage patterns are spaced apart from each other in first and second directions and each respectively comprise first and second magnetic tunnel junction patterns; and
forming information storage patterns on the cell region and the interface region of the substrate by removing a portion of the preliminary information storage patterns on the interface region of the substrate.

8. The method of claim 7, wherein the forming the preliminary information storage patterns comprises:
sequentially forming a preliminary lower electrode, a preliminary magnetic tunnel junction pattern, and a preliminary upper electrode on the cell region, the peripheral region, and the interface region of the substrate; and
patterning the preliminary lower electrode, the preliminary magnetic tunnel junction pattern, and the preliminary upper electrode.

9. The method of claim 7, wherein the removing the preliminary information storage patterns on the interface region of the substrate comprises:
forming an upper insulating film that at least partially exposes the portion of the preliminary information storage patterns on the interface region of the substrate; and
etching a portion of the upper insulating film and the portion of the preliminary information storage patterns to form the information storage patterns.

10. The method of claim 7, further comprising:
forming a spacer that extends around the information storage patterns and is on the substrate.

11. A magnetic memory device comprising:
a substrate;
an array comprising information storage patterns that are spaced apart from each other in a first direction and a second direction on the substrate, the information storage patterns comprising magnetic tunnel junction patterns; and
a spacer that extends around at least a portion of the array and is on the substrate,
wherein the information storage patterns comprise normal information storage patterns at a central portion of the array and dummy information storage patterns at a peripheral portion of the array, and
wherein the dummy information storage patterns are electrically insulated from conductive elements in the substrate.

12. The magnetic memory device of claim 11, wherein:
the spacer comprises convex portions that extend in an extension direction in one of the first direction or the second direction toward the array, and
in the one of the first direction or the second direction, a distance between a first of the convex portions and an adjacent one of the dummy information storage patterns is equal to a distance between adjacent ones of the normal information storage patterns.

13. The magnetic memory device of claim 11, wherein in a plan view, at least one of the information storage patterns has a circular shape.

14. The magnetic memory device of claim 11, wherein the dummy information storage patterns comprise first sub-information storage patterns having a circular shape in a plan view and second sub-information storage patterns having a partially cut circular shape in the plan view.

15. The magnetic memory device of claim 14, wherein the second sub-information storage patterns are at an outermost part of the array.

16. The magnetic memory device of claim 11, wherein the dummy information storage patterns are spaced apart from the spacer in the first direction and the second direction.

17. The magnetic memory device of claim 11, wherein at least some of the dummy information storage patterns are in contact with the spacer.

18. The magnetic memory device of claim 11, wherein:
the substrate comprises a cell region, a peripheral region extending around the cell region, and an interface region between the cell region and the peripheral region,
the array is on the cell region and the interface region of the substrate, and
the spacer is on the peripheral region of the substrate.

19. The magnetic memory device of claim 11, wherein:
the substrate comprises a cell region, a peripheral region extending around the cell region, and an interface region between the cell region and the peripheral region,
the array is on the cell region and the interface region of the substrate, and
the spacer is on the interface region of the substrate.

20. The magnetic memory device of claim 11, wherein:
the substrate comprises a cell region, a peripheral region extending around the cell region, and an interface region between the cell region and the peripheral region,
the array is on the cell region and the interface region of the substrate, and
the spacer is on the peripheral region and the interface region of the substrate.
